(19) United States
(12) Patent Application Publication
(10) Pub. No.: US 2023/0274981 A1
(43) Pub. Date: Aug. 31, 2023

(54) METHOD FOR FORMING DIFFUSION BREAK STRUCTURE IN FIN FIELD EFFECT TRANSISTOR

(71) Applicant: Shanghai Huali Integrated Circuit Corporation, Shanghai (CN)

(72) Inventors: Xiaobo GUO, Shanghai (CN); Yu ZHANG, Shanghai (CN); Rui QIAN, Shanghai (CN); Lulu LAI, Shanghai (CN)

(21) Appl. No.: 18/164,523

(22) Filed: Feb. 3, 2023

(30) Foreign Application Priority Data
Feb. 28, 2022 (CN) 202210185332.6

(51) Int. Cl. H01L 21/8234; H01L 29/66

(52) U.S. Cl. CPC H01L 21/823481; H01L 29/66795

(57) ABSTRACT

A method is disclosed for forming a diffusion break structure in a fin field effect transistor, including: performing a lithography process on a substrate to form a lithography pattern of a single diffusion break structure; etching the substrate to form an etched single diffusion break structure; performing an epitaxial growth process, forming an epitaxial-layer-covered single diffusion break structure by depositing an epitaxial layer on the surface of the substrate and the bottom surface and sidewalls of the etched single diffusion break structure; etching the epitaxial layer and the substrate in the single diffusion break structure, to form a plurality of fins arranged at intervals; forming an isolation layer between the two adjacent fins, wherein the top surface of the fins is higher than the top surface of the isolation layer; and forming gates spaced apart from each other respectively at the top of the isolation layer.

### CROSS-REFERENCES TO RELATED APPLICATIONS

This application claims the priority to Chinese patent application No. CN 202210185332.6, entitled “METHOD FOR FORMING DIFFUSION BREAK STRUCTURE IN FIN FIELD EFFECT TRANSISTOR”, and filed on Feb. 28, 2022 at CNIPA, the content of which is incorporated herein by reference in its entirety.

### TECHNICAL FIELD

The present application relates to the technical filed of semiconductors, in particular, to a method for forming a diffusion break structure in a fin field effect transistor.

### BACKGROUND

The increasingly high integration level of semiconductor devices on a chip enables the ever smaller technology nodes in the semiconductor manufacturing process. When the process developed into the 14 nm node, the transistor structures also moved from planar structures to three-dimensional fin field effect transistors (FinFET). In a FinFET transistor, the source, drain, and channel of the transistor are formed by tall and thin fins on the substrate, and the adjacent fins are isolated from each other by layers of isolation materials. The gate abuts on the two side walls and the top tip of the fin, so the fin has an increased channel area, which is conducive to the gate control to the channel, so the device significantly reduces leakage from the channel. In addition, since the integration level of fin field effect transistor devices has increased, a single diffusion break (a.k.a. SDB) or double diffusion break (DDB) structure is required. The single diffusion break structure isolates adjacent fins from interfering with one another, so as to avoid a source-drain bridging between the adjacent fins.

### BRIEF SUMMARY

The present application discloses a method for forming a diffusion break structure in a fin field effect transistor, to eliminate defects of the non-full cut-off in a fin caused by photoresist bridging.

The disclosed method for forming the diffusion break structure in the fin field effect transistor at least includes the following steps:
step 1, performing a lithography process on a substrate to form a lithography pattern of a single diffusion break structure, wherein an initial opening width of the lithography pattern is c;
step 2, etching the substrate to form an etched single diffusion break structure, wherein an opening width of the etched single diffusion break structure is d;
step 3, performing an epitaxial growth process, and forming an epitaxial layer on a surface of the substrate, a bottom surface and side walls of the etched single diffusion break structure, wherein a thickness of the epitaxial layer is t, wherein the epitaxial-layer-covered single diffusion break structure has an opening width b;
step 4, etching the substrate and the epitaxial-layer-covered single diffusion break structure, to form a plurality of fin structures, wherein the plurality of fin structures are arranged at intervals;
step 5, forming an isolation layer between two adjacent ones of the plurality of fin structures, wherein the adjacent fins are isolated from each other by the isolation layer, wherein top surfaces of the plurality of fin structures is higher than a top surface of the isolation layer; and
step 6, forming a plurality of gates spaced apart from each other respectively at the top surface of the isolation layer, at side walls and the top surfaces of the plurality of fin structures in the single diffusion break structure.

In an example, the substrate in step 1 provides a support for forming the fin.

In an example, the substrate in step 1 is a silicon substrate.

In an example, the substrate in step 1 is a substrate undergoing ion implantation or epitaxial processing.

In an example, the substrate in step 1 is provided with a hard mask.

In an example, in step 1, before formation of the lithography pattern, a carbon layer and a bottom antireflection layer are formed on the substrate.

In an example, in step 1, before formation of the lithography pattern, a carbon layer or a bottom antireflection layer is formed on the substrate.

In an example, the opening width d of the single diffusion break structure in step 2 depends on the opening width c of the lithography pattern and an etch bias of an etching process.

In an example, the opening width of the single diffusion break structure in step 2 is d, and d=c−x, wherein c is the opening width of the lithography pattern in step 1, and x is the etch bias of the etching process in step 2.

In an example, in this method, after step 2, a double patterning technique including step 1 and step 2 is repeated to obtain a single diffusion break structure with a smaller spacing between two adjacent ones of the single diffusion break structures.

In an example, the epitaxial growth process in step 3 is homoepitaxy.

In an example, the epitaxial growth process in step 3 is heteroepitaxy.

In an example, doping processing is performed on the formed epitaxial layer in step 3.

In an example, a method for forming the fin in step 4 is a single lithography-etch method.

In an example, a method for forming the fin in step 4 is a lithography-etch-lithography-etch double patterning technique.

In an example, a method for forming the fin in step 4 is a self aligned double patterning technique.

In an example, a method for forming the fin in step 4 is a self aligned quadruple patterning technique.

In an example, a method for forming the isolation layer in step 5 includes: sub-step 1, depositing an isolation material; and sub-step 2, removing the redundant isolation material using a method of chemical mechanical polishing or etch back, so as to form the isolation layer.

As described above, the method for forming a diffusion break structure in a fin field effect transistor of the present application has the following beneficial effects: A lithography process window is improved, thus avoiding the use of the more expensive extreme ultraviolet lithography (EUVL) process. Moreover, bridge defects in the lithography pattern of the single diffusion break structure are reduced, solving the problem of non-full cut-off of the fin in the conventional process and thereby improving the product yield. In addition, in the present application, the epitaxial process enables the fin to include two layers of materials: the substrate material and the epitaxial layer. Therefore, parameters such as the doping elements, concentration, temperature, and gas flow rate during doping the epitaxial layer may be adjusted to satisfy the requirements of the resultant device, to improve the device performance.

### BRIEF DESCRIPTION OF THE DRAWINGS

FIG. 1 is a schematic diagram of a structure after a lithography patterning during forming the single diffusion break structure according to the present disclosure.

FIG. 2 is a schematic diagram after etching the single diffusion break structure formed according to the present disclosure.

FIG. 3 is a schematic diagram showing after an epitaxial layer deposited on the single diffusion break structure according to the present disclosure.

FIG. 4 is a schematic diagram showing a plurality of fins formed at intervals on the single diffusion break structure according to the present disclosure.

FIG. 5 is a schematic diagram of a structure where an isolation layer is formed according to the present disclosure.

FIG. 6 is a schematic diagram of a structure where a gate is formed according to the present disclosure.

FIG. 7 is a flowchart of a method for forming a diffusion break structure in a fin field effect transistor according to the present disclosure.

### DETAILED DESCRIPTION OF THE DISCLOSURE

The implementation manners of the present application are described below using specific examples, and those skilled in the art could easily understand other advantages and effects of the present application from the content disclosed in the description. The present application can also be implemented or applied in other different specific implementation manners, and various details in the Description can also be modified or changed based on different views and applications without departing from the spirit of the present application.

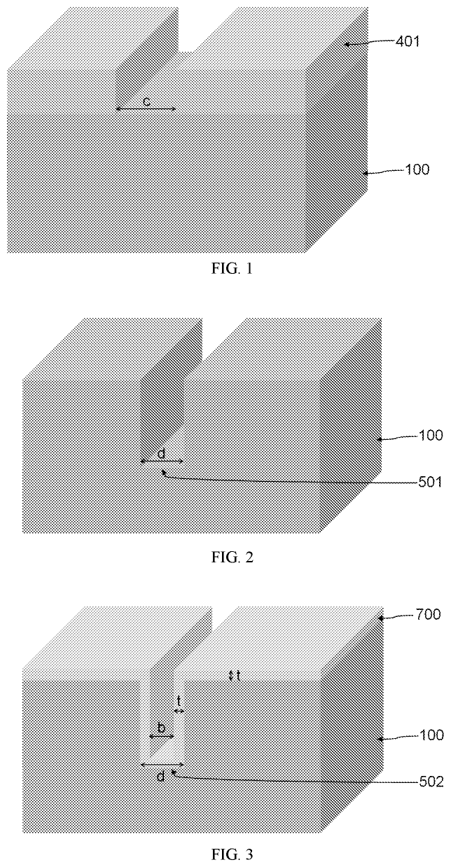

Please refer to FIGS. 1-7. It should be noted that the figures provided in the embodiments are only intended to illustrate the basic concept of the present application in a schematic way, so the figures only show the components related to the present application instead of being drawn according to the number, shape, and size of components in actual implementation. The type, number, and proportion of the components in actual implementation can be changed randomly, and the layout type of the components may be more complex.

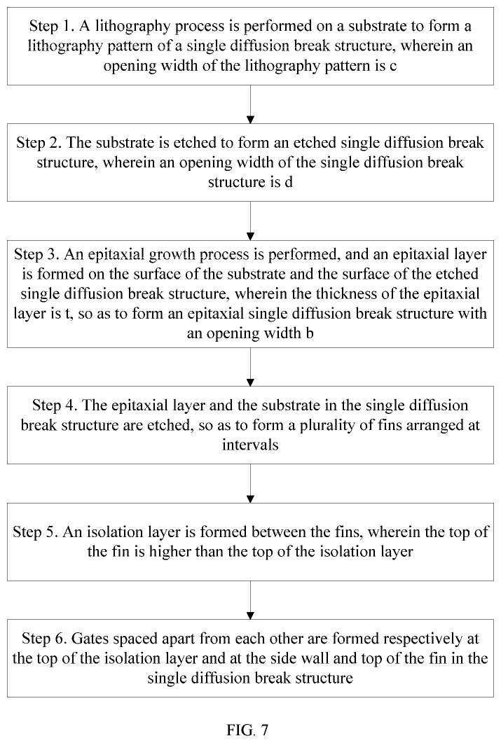

The present application provides a method for forming a diffusion break structure in a fin field effect transistor. Referring to FIG. 7, FIG. 7 shows a flowchart of the method for forming the diffusion break structure in the fin field effect transistor in the present application. The method at least includes the following steps.

Step 1. A lithography process is performed on a substrate to form the pattern of the single diffusion break structure, an opening width of the lithography pattern is c. Referring to FIG. 1, FIG. 1 is a schematic diagram of a structure of the lithography pattern of the single diffusion break structure in the present application. In step 1, the lithography process is performed on the substrate 100 to form the lithography pattern 401 of the single diffusion break structure, wherein the opening width of the lithography pattern 401 is c.

In this embodiment of the present application, in step 1, the fin is formed at a part of the substrate 100.

In this embodiment of the present application, the substrate 100 in step 1 is a silicon substrate.

In this embodiment of the present application, the substrate 100 in step 1 is a substrate undergoing ion implantation or epitaxial processing. That is, in this embodiment, the ion implantation or epitaxial processing may be performed on the substrate according to the process requirements.

In this embodiment of the present application, the substrate in step 1 is provided with a hard mask. That is, according to the process requirements, an etch hard mask can be grown on the substrate for an etching process in subsequent step 2.

In this embodiment of the present application, in step 1, before formation of the lithography pattern, a carbon layer and a bottom antireflection layer are formed on the substrate. In this embodiment of the present application, in step 1, before formation of the lithography pattern, a carbon layer or a bottom antireflection layer is formed on the substrate. That is, according to the process requirements, spin coating can be performed to form the carbon layer and/or the bottom antireflection layer under the lithography pattern 401.

Step 2. The substrate is etched to form an trenched single diffusion break structure, wherein an opening width of the trenched single diffusion break structure is d. Referring to FIG. 2, FIG. 2 is a schematic diagram of the single diffusion break structure formed in the present application. In step 2, the substrate 100 is etched to form the single diffusion structure 501.

In this embodiment of the present application, the opening width d of the single diffusion break structure in step 2 depends on the opening width c of the lithography pattern and an etch bias of an etching process.

In this embodiment of the present application, the opening width of the single diffusion break structure in step 2 is d=c−x, wherein c is the opening width of the lithography pattern in step 1, and x is the etch bias of the etching process in step 2.

In this embodiment of the present application, in this method, after step 2, a double patterning technique of step 1 and step 2 is repeated to obtain the single diffusion break structure at a higher density, i.e. smaller spacing between the trenched structures. That is, according to the process requirements, in step 1 and step 2 of the method, the double patterning technique, i.e., “Litho-Etch-Litho-Etch (LELE)” method, can be used, and a single diffusion break structure with a smaller spacing is obtained by repeating step 1 and step 2.

That is, the opening width d of the etched single diffusion break structure depends on specific conditions of the etching process and the opening width c of the lithography pattern of the single diffusion break structure in step 1, i.e., d=c−x, wherein x is the etch bias of the etching process.

Step 3. An epitaxial growth process is performed to form an epitaxial layer on the surface of the substrate and the surface of the etched single diffusion break structure, wherein the thickness of the epitaxial layer is t, so as to form an epitaxial single diffusion break structure with an opening width b. Referring to FIG. 3, FIG. 3 is a schematic diagram showing the single diffusion break structure after an epitaxial layer deposition according to the present disclosure. In step 3, the epitaxial growth process is performed, and the epitaxial layer 700 is formed following the surface of the substrate and the bottom surface and side walls of the trenched single diffusion break structure, wherein the thickness of the epitaxial layer 700 is t, therefore the remaining trenched epitaxial single diffusion break structure 502 has the remaining opening width b.

In this embodiment of the present application, the epitaxial growth process in step 3 is homoepitaxy.

In other embodiments, the epitaxial growth process in step 3 may be heteroepitaxy. That is, the epitaxy is “homoepitaxy” where the epitaxial layer and the substrate are made of the same material. Alternatively, the epitaxy may be “heteroepitaxy” where the epitaxial layer and the substrate are made of different materials.

In this embodiment of the present application, doping processing is performed on the formed epitaxial layer in step 3. The parameters such as the doping element and concentration, doping temperature, and gas flow rate during growth of the epitaxial layer may be adjusted to satisfy different device performance requirements. The opening width of the epitaxial single diffusion break structure is b=d−2t=c−x−2t, wherein the opening width b is also an opening width of a final single diffusion break structure.

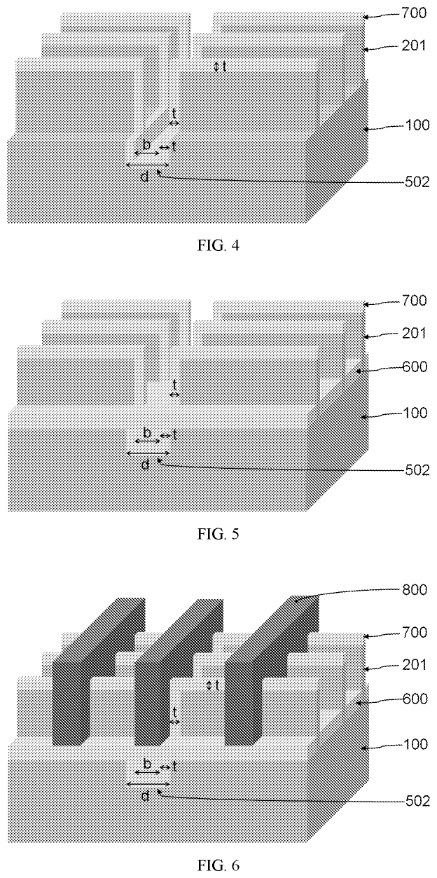

Step 4. The epitaxial layer and the substrate in the single diffusion break structure are etched, so as to form a plurality of fins arranged at intervals. Referring to FIG. 4, FIG. 4 is a schematic diagram of the plurality of fins arranged at intervals formed in the present application. In step 4, the epitaxial layer 700 and the substrate 100 in the single diffusion break structure are etched, so as to form the plurality of fins 201 arranged at intervals.

In this embodiment of the present application, a method for forming the fin in step 4 is a single lithography-etch method.

In other embodiments, a method for forming the fin in step 4 is a lithography-etch-lithography-etch double patterning technique.

In other embodiments, a method for forming the fin in step 4 is a self aligned double patterning technique.

In other embodiments, a method for forming the fin in step 4 is a self aligned quadruple patterning method. That is, the method for forming the fin includes but is not limited to: the single lithography-etch method, the lithography-etch-lithography-etch (LELE) double patterning technique, the self aligned double patterning (SADP) method, and the self aligned double patterning (SADP) method.

Step 5. An isolation layer is formed between the fins, wherein the top of the fin is higher than the top of the isolation layer. Referring to FIG. 5, FIG. 5 is a schematic diagram of a structure where an isolation layer is formed in the present application. In step 5, the isolation layer 600 is formed between all two of the fins 201, wherein the top point of the fin is higher than the top point of the isolation layer.

In this embodiment of the present application, a method for forming the isolation layer in step 5 includes: sub-step 1, depositing an isolation material; and sub-step 2, removing the redundant isolation material using a method of chemical mechanical polishing or etch back, so as to form the isolation layer.

Step 6. Gates spaced apart from each other are formed respectively at the top of the isolation layer and at the side wall and top of the fin in the single diffusion break structure. Referring to FIG. 6, FIG. 6 is a schematic diagram of a structure where the gate is formed in the present application. In step 6, the gates 800 spaced apart from each other are formed respectively at the top of the isolation layer and at the side wall and top of the fin in the single diffusion break structure.

Since the opening width b of the single diffusion break structure is necessarily less than or equal to the width of the gate 800 and in a 14 nm FinFET process, the width of the gate 800 is generally 20 nm, the opening width b of the single diffusion break structure is necessarily less than 20 nm. Moreover, the opening width b of the single diffusion break structure depends on the opening width a of the lithography pattern of the single diffusion break structure, i.e., b=a−x, wherein x is the etch bias, so the opening width a cannot be excessively large, usually less than 50 nm. The formation of a lithography pattern with an opening width a less than 50 nm poses a very high challenge to the lithography process, resulting in a relatively small process window. In the actual lithography process (step 2), it is easy to form a photoresist bridge at an opening of the lithography pattern, resulting in non-full cut-off of the fin in the subsequent etching process (step 3), making the single diffusion break structure invalid, and thus affecting the final performance of the device.

In the method for forming a diffusion break structure in a fin field effect transistor of the present application, as can be seen from step 1 to step 3, the opening width of the lithography pattern of the single diffusion break structure is c=b+x+2t, while in the conventional process method, the opening width of the lithography pattern of the single diffusion break structure is a=b+x. After formula conversion, it can be seen that c=a+2t. That is, the opening width c of the lithography pattern of the single diffusion break structure in the present application can be 2t larger than the opening width a of the lithography pattern of the single diffusion break structure in the conventional process method. A larger opening width of the lithography pattern can achieve the following technical effects: on the one hand, a lithography process window is improved, thus avoiding the use of a more expensive extreme ultraviolet lithography process. On the other hand, bridge defects in the lithography pattern of the single diffusion break structure are reduced, solving the problem of non-full cut-off of the fin 200 in the conventional process and thereby improving the product yield. In addition, in the present application, due to the use of the epitaxial process, the fin is composed of two layers of materials: the substrate material and the epitaxial layer. Therefore, parameters such as doping element and concentration, temperature, and gas flow rate of the epitaxial layer may be adjusted to satisfy the requirements of the final device, such that the device performance can be flexibly adjusted.

To sum up, the present application improves the lithography process window, thus avoiding the use of a more expensive extreme ultraviolet lithography process. Moreover, bridge defects in the lithography pattern of the single diffusion break structure are reduced, solving the problem of non-full cut-off of the fin in the conventional process and thereby improving the product yield. In addition, in the present application, due to the use of the epitaxial process, the fin is composed of two layers of materials: the substrate material and the epitaxial layer. Therefore, parameters such as doping element and concentration, temperature, and gas flow rate of the epitaxial layer may be adjusted to satisfy the requirements of the final device, such that the device performance can be flexibly adjusted. Therefore, the present application effectively overcomes various challenges and defects in the existing techniques, and thus contributes to high value to the industry.

The above embodiments merely exemplify the principle and effects of the present application, and are not intended to limit the present application. Any person familiar with the art can modify or change the above embodiments without violating the spirit and scope of the present application. Therefore, all equivalent modifications or changes made by those with ordinary kills and knowledge in the art without departing from the spirit and technical ideas disclosed by the present application shall still be covered by the claims of the present application.

What is claimed is:

1. A method for forming a diffusion break structure in a fin field effect transistor, wherein the method at least comprises:
step 1, performing a lithography process on a substrate to form a lithography pattern of a single diffusion break structure, wherein an initial opening width of the lithography pattern is c;
step 2, etching the substrate to form an etched single diffusion break structure, wherein an opening width of the etched single diffusion break structure is d;
step 3, performing an epitaxial growth process, and forming an epitaxial layer on a surface of the substrate, a bottom surface and side walls of the etched single diffusion break structure, wherein a thickness of the epitaxial layer is t, wherein the epitaxial-layer-covered single diffusion break structure has an opening width b;
step 4, etching the substrate and the epitaxial-layer-covered single diffusion break structure, to form a plurality of fin structures, wherein the plurality of fin structures are arranged at intervals;
step 5, forming an isolation layer between two adjacent ones of the plurality of fin structures, wherein the adjacent fins are isolated from each other by the isolation layer, wherein top surfaces of the plurality of fin structures is higher than a top surface of the isolation layer; and
step 6, forming a plurality of gates spaced apart from each other respectively at the top surface of the isolation layer, at side walls and the top surfaces of the plurality of fin structures in the single diffusion break structure.

2. The method for forming the diffusion break structure in the fin field effect transistor according to claim 1, wherein in step 1, the plurality of fin structures are formed in a portion of the substrate.

3. The method for forming the diffusion break structure in the fin field effect transistor according to claim 1, wherein the substrate in step 1 is a silicon substrate.

4. The method for forming the diffusion break structure in the fin field effect transistor according to claim 1, wherein an ion implantation process or epitaxial growth process has been applied to the substrate in step 1.

5. The method for forming the diffusion break structure in the fin field effect transistor according to claim 1, wherein the substrate in step 1 is provided with a hard mask.

6. The method for forming the diffusion break structure in the fin field effect transistor according to claim 1, wherein in step 1, before formation of the lithography pattern, a carbon layer and a bottom antireflection layer are both formed on the substrate.

7. The method for forming the diffusion break structure in the fin field effect transistor according to claim 1, wherein in step 1, before formation of the lithography pattern, a carbon layer or a bottom antireflection layer is formed on the substrate.

8. The method for forming the diffusion break structure in the fin field effect transistor according to claim 1, wherein the opening width d of the etched single diffusion break structure depends on the initial opening width c of the lithography pattern and an etch bias of the etching process in step 2.

9. The method for forming the diffusion break structure in the fin field effect transistor according to claim 8, wherein the opening width d of the etched single diffusion break structure in step 2 is d=c−x, wherein c is the initial opening width of the lithography pattern in step 1, and x is the etch bias of the etching process in step 2.

10. The method for forming the diffusion break structure in the fin field effect transistor according to claim 1, wherein after step 2, a double patterning technique including step 1 and step 2 is repeated to obtain a doubled single diffusion break structure with a smaller spacing between two adjacent ones of the single diffusion break structures.

11. The method for forming the diffusion break structure in the fin field effect transistor according to claim 1, wherein the epitaxial growth process in step 3 is homoepitaxy.

12. The method for forming the diffusion break structure in the fin field effect transistor according to claim 1, wherein the epitaxial growth process in step 3 is heteroepitaxy.

13. The method for forming the diffusion break structure in the fin field effect transistor according to claim 1, wherein a doping process is performed on the epitaxial layer in step 3.

14. The method for forming the diffusion break structure in the fin field effect transistor according to claim 1, wherein forming the plurality of fin structures in step 4 comprises a single lithography-etch process.

15. The method for forming the diffusion break structure in the fin field effect transistor according to claim 1, wherein forming the plurality of fin structures in step 4 comprises double patterning technique having lithography-etch-lithography-etch steps.

16. The method for forming the diffusion break structure in the fin field effect transistor according to claim 1, wherein forming the plurality of fin structures in step 4 is a self aligned double patterning technique.

17. The method for forming the diffusion break structure in the fin field effect transistor according to claim 1, wherein forming the plurality of fin structures in step 4 is a self aligned quadruple patterning technique.

18. The method for forming the diffusion break structure in the fin field effect transistor according to claim 1, wherein forming the isolation layer in step 5 further comprises:
sub-step 1, depositing an isolation material; and
sut-step 2, removing redundant isolation material using chemical mechanical polishing or etching back to form the isolation layer.
